(19) United States
(12) Patent Application Publication
(10) Pub. No.: US 2004/0089864 A1
(43) Pub. Date: May 13, 2004

(54) Light emitting diode and method of making the same

(76) Inventors: Wu-Sheng Chi, Hsinchu (TW); Tzer-Perng Chen, Hsinchu (TW); Chih-Sung Chang, Hsinchu (TW); Tzong-Liang Tsai, Hsinchu (TW)

Correspondence Address: LOWE HAUPTMAN GOPSTEIN GILMAN & BERNER, LLP, Suite 310, 1700 Diagonal Road, Alexandria, VA, 22314, US

(21) Appl. No.: 10/396,821

(22) Filed: Mar. 26, 2003

(30) Foreign Application Priority Data
Nov. 8, 2002 (TW) 91132980

(51) Int. Cl. H01L 21/00; H01L 27/15; H01L 31/12; H01L 33/00

(52) U.S. Cl. 257/79; 438/22; 438/35; 438/46; 257/90

(57) ABSTRACT

The present invention provides a structure of white light-emitting diode (LED) and a method of making the same. The structure according to the present invention comprises two LED chips that have light-emitting layers of multi-layer epitaxial structure and emit the lights of one or more colors. The structure comprises an LED emitting the visible light of short wavelength, and another LED emitting the visible light of long wavelength. Wherein, at least one chip in the present invention has two or more transition energy levels used for emitting two or more colored lights. With the use of the present invention, multiple colored lights emitted by the LED can be mixed into full-spectral white light source having excellent color rendering property and high light emitting efficiency. The white LED in the present invention is an ideal light source for general-purpose illumination applications

### FIELD OF THE INVENTION

The present invention relates to a structure of white light emitting diode (LED) light source and the method of making the same, and more particularly, to an LED structure that can emit two or more colored lights and the manufacturing method thereof.

### BACKGROUND OF THE INVENTION

Semiconductor light emitting diode (LED) has become a promising device for general-purpose illumination applications. LED has the features of excellent durability, long operation life, low power consumption, no mercury containing and potentially high efficiency. White LED is an illumination light source that is good for environmental protection and energy saving. The conventional illumination devices such as incandescent bulbs are cheap in price, but, unfortunately, they have drawbacks of low efficiency, high power consumption, short operation life and fragility. The fluorescent lamps are energy saving devices but still fragile, and contain mercury causing problems of environmental pollution. Therefore, the white LEDs are ideal light sources for general-purpose illumination applications of new generation.

With regard to the manufacturing technology of white LED, there are five relative popular methods existing currently. The first method is to utilize an AlInGaN LED chip emits blue light and a phosphor (yttrium aluminum garnet, YAG) that emits in the yellow region. A part of the blue light is absorbed in the phosphor layer and down-converted to yellow light. The rest of the blue emission escapes into the transparent resin. The blue and yellow lights can be mixed into white light. Wherein the method is advantageously simple and easily enabled, but is disadvantageously poor in color rendition resulted from lacking of red color content, and in color-shifting problem as operation current increases. Additionally, the LED made by the first method has low illumination efficiency and aging problems. Therefore it is not an ideal illumination light source.

The second method for manufacturing a white LED is to use the combination of multiple LEDs of red AlInGaP material, green AlInGaN material and blue AlInGaN material as a group of white light source. The operating currents applied on these LED chips need to be well controlled to achieve the purpose of white color mixing. Since the method does not use phosphors for color conversion, the illumination efficiency is much higher than that of the first method, and it also avoids phosphor-related aging problems. One of the disadvantages is a more complex design that might increase cost. Another disadvantage is narrow emission lines from the LEDs cause poor color rendering properties. On the other hand, the second method utilizes two expensive AlInGaN LED chips, it is not worthy in the aspect of material cost.

The third method for manufacturing a white LED is based on exploiting an ultra-violent (UV) LED for excitation of a set of phosphors. The visible part of the emitting spectrum is completely generated by phosphors. The UV light emitted by the LED excites the phosphors to emit red, green and blue lights, and these tri-color lights are further mixed into white light. However, moving the pump source into the UV spectral range results in a reduced radiant efficiency because of enhanced energy loss in the conversion process. Besides, the conversion efficiencies of the phosphors are still poor, and the packaging materials have the aging problems due to the UV light damages. Therefore this is not a proper way to produce white illumination source.

The fourth method of generating white light is the technology by using the ZnSe material systems. Wherein a CdZnSe film is formed on a ZnSe single crystal substrate. The CdZnSe film emits blue light by applying electricity thereto. A part of blue light is absorbed by the substrate and then emits yellow light. Finally, the blue and yellow lights can be mixed into white light. The operation theory is different from the aforementioned methods that utilize a blue or UV LED together with phosphors. This white LED uses only one chip and does not need to use the phosphor material to produce white light. Unfortunately, the luminous efficiency thereof is relatively too low, and the operation life thereof is relatively too short. Thus the method cannot be practically enabled.

The fifth method for manufacturing a white light LED is also based on the principle of mixing blue and yellow lights into white light, wherein the blue and yellow LED chips are combined in a set to generate white light. This dichromatic LED system features the highest efficacy of all white solid-state sources. However, the color rendering property of this kind of LED is extremely poor. It is not suitable for general illumination applications.

In view of potential applications, the designs of the white illuminators aim at a combination of high efficiency, high color rendering and reasonable cost. The present invention provides a white LED structure and a method for making the same, so as to achieve the aforementioned objectives.

### SUMMARY OF THE INVENTION

The present invention provides a white LED structure and a method for making the same. The device consists of two LED chips, one is AlInGaN LED for emitting shorter visible spectra, the other is AlInGaP LED for emitting longer visible spectra. At least one chip in this white LED structure has two or more transition energy levels used for emitting two or more colored lights. The multiple colored lights generated from the white LED can be mixed into a full-spectral white light. There is no phosphors conversion layer used in this white LED structure. Therefore, its color rendering property and illumination efficiency are excellent. The general color rendering index (Ra) could be as high as 94, which is close to the incandescent and halogen sources, while the Ra of binary complementary white (BCW) LED is about 30˜45. Moreover, compared to the expensive ternary RGB (Red AlInGaP+Green AlInGaN+Blue AlInGaN) white LED sources, the white LED of the present invention uses only one AlInGaN chip in combination with one cheap AlInGaP chip to form a low cost, high luminous performance white light source. The white LED of the present invention is an ideal light source for general-purpose illumination applications.

The LED structures of the present invention comprise a first ohmic contact metal electrode layer and a second ohmic contact metal electrode layer, contacting an N-typed GaAs substrate and a P-typed ohmic contact epitaxial layer, respectively. The active layers of the LEDs may be multi-quantum well (MQW) structures. Moreover, the present invention provides a method enabling an LED to emit multiple colored lights, wherein the band-gap engineering principle is applied in the active layer to design one or more transition energy levels, so as to obtain different colored lights simultaneously. For example, we can modify the quantum well width, the material composition, or the strain inside the material to change the transition energy level as well as the color of the emitted light. Therefore, one advantage of the present invention is to provide a simple structure of white LED light source, wherein the light spectrum emitted therefrom covers most of visible wavelength range, thus having high color rendering property.

Another advantage of the present invention is that the white light source can be generated without using phosphor materials and the related coating processes, thereby greatly enhancing the production yield. Moreover, the present invention can merely use one LED emitting the visible light of short wavelength (such as AlInGaN or ZnSe chip), in combination with the other one LED emitting the visible light of long wavelength (such as AlInGaP or AlGaAs chip), to form a white illumination light source of excellent properties and low cost.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic diagram showing the epitaxial structure of an AlInGaP LED, according to a preferred embodiment of the present invention;

FIG. 2 is a schematic diagram showing the quantum well structure obtained by varying the aluminum content x in the quantum well material of the active layer of the AlInGaP LED, according to a first preferred embodiment of the present invention, wherein the x is to changed to 0, 0.08, 0.13, 0.22 and 0.30 in sequence;

FIG. 3 is a spectral diagram showing the colored light having a near-full spectral continuous spectrum obtained by varying the aluminum content x in the quantum well material of the active layer of the AlGaInP LED as well as mixing the lights (470 nm and 540 nm in wavelength) emitted from a green AlInGaN LED chip, according to the first preferred embodiment of the present invention, wherein the x is to changed to 0, 0.08, 0.13, 0.22 and 0.30 in sequence;

FIG. 4 is a schematic diagram showing the quantum well structure of an AlInGaP LED chip having duel transition energy gaps, according to a second preferred embodiment of the present invention;

FIG. 5 is a diagram showing the light spectrum emitted from the combination of the AlInGaP LED chip having dual transition energy gaps (emitting yellow light of 590 nm and red light of 615 nm in wavelength) and the AlInGaN LED chip emitting blue-green light (of 505 nm in wavelength), according to the second preferred embodiment of the present invention; and

FIG. 6 is a diagram showing the light spectrum emitted from the combination of the AlInGaN LED chip having dual transition energy gaps (emitting blue light of 470 nm and green light of 540 nm in wavelength) and the AlInGaP LED chip emitting red light (of 625 nm in wavelength), according to a third preferred embodiment of the present invention.

### DETAILED DESCRIPTION OF THE PREFERRED EMBODIMENT

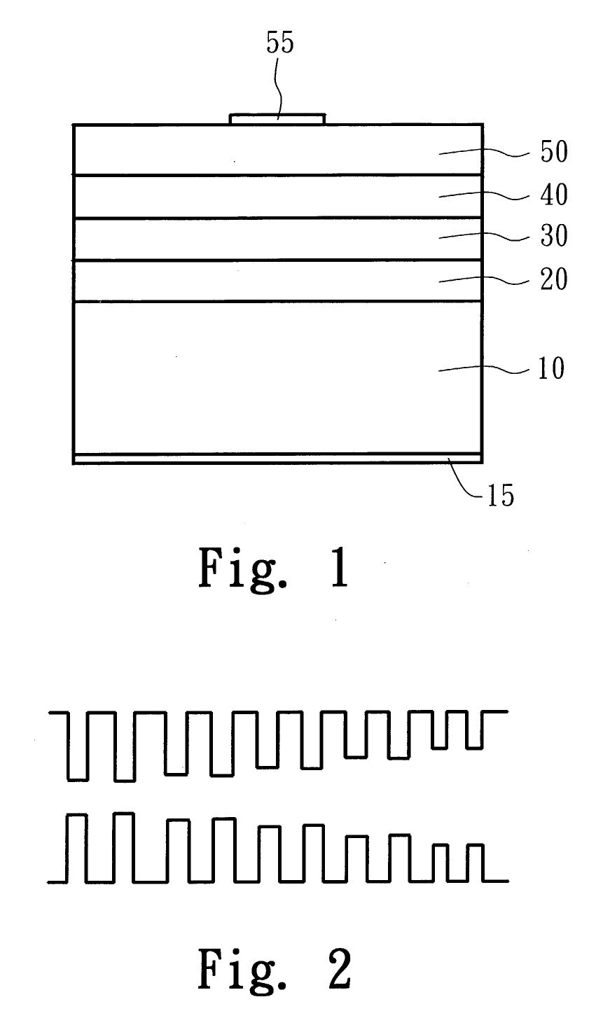

The present invention discloses a white LED structure and a method of making the same. For explaining the present invention in more details and with more completion, the following description is stated with reference to FIGS. 1-6.

Firstly, an AlInGaP LED is used as an example for explanation. Please refer to FIG. 1. According to a preferred embodiment of the present invention, an LED epitaxial structure comprises the following layers stacked in sequence: an N-typed GaAs substrate 10, an N-typed (AlₓGa₁₋ₓ)_{0.5}In_{0.5}P lower cladding layer 20, an (AlₓGa₁₋ₓ)_{0.5}In_{0.5}P active layer 30, a P-typed (AlₓGa₁₋ₓ)_{0.5}In_{0.5}P upper cladding layer 40 and a P-typed ohmic contact epitaxial layer 50. Moreover, the structure of the present invention further comprises a first ohmic contact metal electrode layer 15 and a second ohmic contact metal electrode layer 55, respectively contacting the N-typed GaAs substrate 10 and the ohmic contact epitaxial layer 50.

The P-typed ohmic contact epitaxial layer 50 can be made of AlGaAs, AlInGaP or GaAsP. As long as a material has greater energy gap than the AlInGaP active layer 30, and does not absorb the light generated from the AlInGaP active layer 30, and also has high carrier concentration for benefiting the formation of ohmic contact, then the material can be selected for forming the P-typed ohmic contact epitaxial layer 50.

The aforementioned (AlₓGa₁₋ₓ)_{0.5}In_{0.5}P active layer 30 can be a multi-quantum wells structure of AlInGaP, wherein the range of aluminum content x can be from 0 to 0.45, and the aluminum content x of the P-typed (AlₓGa₁₋ₓ)_{0.5}In_{0.5}P upper cladding layer 40 and that of the N-typed (AlₓGa₁₋ₓ)_{0.5}In_{0.5}P lower cladding layer 20 are controlled between 0.5 and 1.0. When the aluminum content x of the (AlₓGa₁₋ₓ)_{0.5}In_{0.5}P active layer 30 is 0, the composition of the (AlₓGa₁₋ₓ)_{0.5}In_{0.5}P active layer 30 is Ga_{0.5}In_{0.5}P; the transition energy thereof is about 1.953 eV; the peak wavelength illumination is 635 nm and is red light. When the aluminum content x of the (AlₓGa₁₋ₓ)_{0.5}In_{0.5}P active layer 30 is 0.22; the transition energy thereof is about 2.157 eV; the peak wavelength illumination is 575 nm and is yellow-green light.

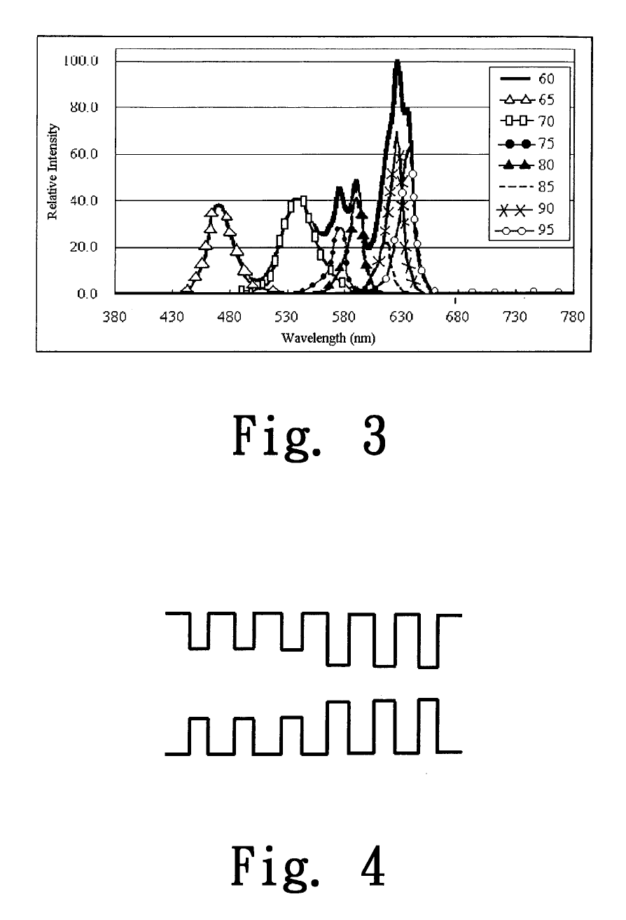

By using the band-gap engineering principle, the present invention designs one or multiple transition energy levels in the material of (AlₓGa₁₋ₓ)_{0.5}In_{0.5}P active layer 30, so as to colored lights of different colors simultaneously, and to generate a white light source having high illumination efficiency and high color rendition by mixing light emitted from the other LED chip (not shown). For example, by sequentially varying the aluminum content x to 0, 0.08, 0.13, 0.22 and 0.30 in the quantum well material of the active layer of the AlInGaP LED, a colored light having near-continuous spectrum can be emitted form one single LED ship, such as shown in FIG. 2 illustrating a schematic diagram showing the quantum well structure. Meanwhile, by mixing the light (of 470 nm and 540 nm in wavelength) emitted from the other blue-green LED chip (not shown), a colored light having full-spectral distribution can be obtained, such as shown in FIG. 3, wherein the light spectrum of each colored light's transition level are illustrated: a light spectrum 65 of blue light transition energy level; a light spectrum 70 of green light transition energy level; a light spectrum 75 of yellow-green light transition energy level; a light spectrum 80 of yellow light transition energy level; a light spectrum 85 of orange light transition energy level; a light spectrum 90 of orange-red light transition energy level; a light spectrum 95 of red light transition energy level; and a white light spectrum 60 that has high color rendition and is formed by mixing various colored lights. Consequently, a full-spectral white illumination light source having high efficiency can be built.

The structure of the other LED chip mentioned above is similar to that shown in FIG. 1, i.e. the other LED chip also comprises the following layers stacked sequentially: a substrate, a lower cladding layer, an active layer, an upper cladding layer and an ohmic contact epitaxial layer, wherein the materials forming those layers are well known by those who are skilled in the art, so that no further description will be stated herein. Further, just as described above, the energy-gap engineering principle applied in forming the AlInGaP active layer 30 is also suitable for use in forming the active layer of the other LED chip.

The correlated color temperature (CCT) obtained from the aforementioned white LED is 3,000 K; the chromaticity coordinates are x (CIE1931)=0.4415, y=0.4045, u (CIE1964)=0.2533, v=0.3482, wherein the general color rendering index (CRI) Ra is 94, which is close to the general standard of white light bulb, and accordingly, is quite suitable for use as a light source for common illumination purpose.

It is merely stated as an example for explanation by using the aforementioned energy-gap engineering technology to adjust the material composition in the AlInGaP active layer, for designing one or multiple transition energy levels. Therefore, the present invention is not limited thereto. The present invention is also suitable for using other energy-gap engineering technologies, wherein one or multiple transition energy level is fabricated from the same single LED chip. For example, the skills of changing the width of quantum well and using the strain effect inside the material all can be properly applied in the present invention. By combining different transition energy levels in accordance with the adjustment of the number of quantum wells and the barrier, white light sources of various spectral distributions can be manufactured for satisfying various applications.

The aforementioned composition ratios are merely stated as examples, such as (AlₓGa₁₋ₓ)_{0.5}In_{0.5}P of the active layer 30, so that the present invention is not limited thereto. Similarly, the present invention is also suitable for use in other ratios. Moreover, the present invention is not limited to the AlInGaP LED of high brightness, but is also suitable for use in other LED materials, such as AlInGaN, AlGaAs or ZnSe etc.

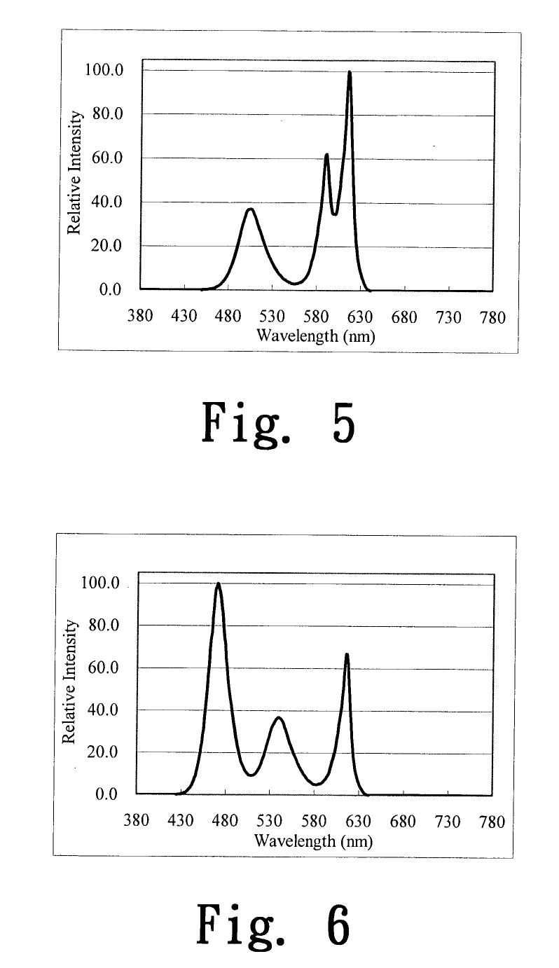

FIG. 4 is a schematic diagram showing the quantum well structure of a second preferred embodiment of the present invention. The aluminum contents x in the quantum well material of the AlInGaP active layer are x=0.13 and x=0.22 respectively, wherein this single LED chip can emit red-yellow dual colored lights of 615 nm and 590 nm in wavelength. After this dual colored lights are mixed with the blue-green light (505 nm in wavelength) emitted from the other AlInGaN LED chip, the white light of which the CCT is 2,400 K, and the chromaticity coordinates are x=0.4994, y=0.4307, u=0.2786, v=0.3604, wherein the color rendering index Ra is 53, which still meets the standard of the basic illumination requirement. As to the light spectrum emitted from the aforementioned two LED chips, please refer to FIG. 5. Accordingly, by combining different transition energy levels in accordance with the adjustment of the number of quantum wells and the barrier, a white light source having different color temperature from the aforementioned first preferred embodiment can thus be made.

The third preferred embodiment of the present invention is to use two LED chips to form a white light source having high efficient three basic colors, red, green and blue. Such as shown in FIG. 6, FIG. 6 is a diagram showing the light spectrum emitted from the combination of the AlInGaN LED chip having dual transition energy gaps (emitting blue light of 470 nm and green light of 540 nm in wavelength) and the AlInGaP LED chip emitting red light (of 625 nm in wavelength), wherein the CCT thereof can reach 10,000 K, and the chromaticity coordinates are x=0.2723, y=0.2874, u=0.1851, v=0.2921, and the color rendering index Ra is 70. The aforementioned combination is extremely suitable for use as a light source of image display, such as a LCD back light source, or the display of three basic colors (red, green and blue) on TV.

To sump up, one advantage of the present invention is to provide a simple white LED light source structure. The light spectrum emitted form this white LED light source covers most of the range of visible lights, so that this white LED light source has abundant colors and high color rendition.

The other advantage of the present invention is that a white light source is formed without using phosphor powder and its coating process, and the illumination efficiency is greatly enhanced. Meanwhile, since the manufacturing process is simple, the product yield can be greatly promoted. Moreover, the present invention can merely use one LED emitting the visible light of short wavelength in combination with the other one LED (such as AlInGaN or ZnSe chip) emitting the visible light of long wavelength, to form a white illumination light source having excellent properties and low cost.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structures.

What is claimed is:

1. A light emitting diode (LED), comprising:
a first LED chip, used for emitting a first visible light having a first light spectrum; and
a second LED chip, used for emitting a second visible light having a second light spectrum, wherein said first visible light is mixed with said second visible light to form a white light source;
wherein said first LED chip and/or said second LED chip have at least two transition energy levels, thereby emitting at least two colored lights.

2. The LED of claim 1, wherein said first LED chip is an AlInGaN LED chip.

3. The LED of claim 1, wherein said first LED chip is a ZnSe LED chip.

4. The LED of claim 1, wherein said second LED chip is an AlInGaP LED chip.

5. The LED of claim 1, wherein said second LED chip is an AlGaAs LED chip.

6. The LED of claim 1, wherein an active layer of said first LED chip and/or an active layer of said second LED chip are the structure of multiple quantum wells (MQWs).

7. The LED of claim 1, wherein an active layer of said first LED chip and/or an active layer of said second LED chip are formed by changing material composition to generate at least two transition energy levels, thereby emitting said at least two colored lights.

8. The LED of claim 1, wherein an active layer of said first LED chip and/or an active layer of said second LED chip are formed by changing quantum well width to generate at least two transition energy levels, thereby emitting said at least two colored lights.

9. The LED of claim 1, wherein an active layer of said first LED chip and/or an active layer of said second LED chip are formed by changing strain in the material to generate at least two transition energy levels, thereby emitting said at least two colored lights.

10. A method for making a LED, comprising:
providing a first LED chip, used for emitting a first visible light having a first light spectrum; and
providing a second LED chip, used for emitting a second visible light having a second light spectrum, wherein said first visible light is mixed with said second visible light to form a white light source;
wherein said first LED chip and/or said second LED chip have at least two transition energy levels, thereby emitting at least two colored lights.

11. The method for making the LED according to claim 10, wherein said first LED chip is an AlInGaN LED chip.

12. The method for making the LED according to claim 10, wherein said first LED chip is a ZnSe LED chip.

13. The method for making the LED according to claim 10, wherein said second LED chip is an AlInGaP LED chip.

14. The method for making the LED according to claim 10, wherein said second LED chip is an AlGaAs LED chip.

15. The method for making the LED according to claim 10, wherein an active layer of said first LED chip and/or an active layer of said second LED chip are the structure of multiple quantum wells (MQWs).

16. The method for making the LED according to claim 10, wherein an active layer of said first LED chip and/or an active layer of said second LED chip are formed by changing material composition to generate at least two transition energy levels, thereby emitting said at least two colored lights.

17. The method for making the LED according to claim 10, wherein an active layer of said first LED chip and/or an active layer of said second LED chip are formed by changing quantum well width to generate at least two transition energy levels, thereby emitting said at least two colored lights.

18. The method for making the LED according to claim 10, wherein an active layer of said first LED chip and/or an active layer of said second LED chip are formed by changing strain in the material to generate at least two transition energy levels, thereby emitting said at least two colored lights.
